(19) United States
(12) Patent Application Publication
(10) Pub. No.: US 2007/0026661 A1
(43) Pub. Date: Feb. 1, 2007

(54) METHOD OF MANUFACTURING A SEMICONDUCTOR DEVICE

(75) Inventors: Michiyoshi TAKANO, Suwa (JP); Kazuhiro KIJIMA, Suwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/458,806

(22) Filed: Jul. 20, 2006

(30) Foreign Application Priority Data
Jul. 27, 2005 (JP) 2005-217344

(51) Int. Cl. H01L 21/44

(52) U.S. Cl. 438/613; 438/631; 438/108

(57) ABSTRACT

A method of manufacturing a semiconductor device includes: (a) preparing a semiconductor chip having a plurality of electrodes; (b) preparing a substrate having a plurality of electrical connection portions; (c) holding the semiconductor chip by a holding tool; (d) planarizing an upper surface of the electrode of the semiconductor chip held by the holding tool; and (e) electrically connecting, after the step (d), the electrode of the semiconductor chip and the electrical connection portion of the substrate.

The entire disclosure of Japanese Patent Application No. 2005-217344, filed on Jul. 27, 2005 is expressly incorporated by reference herein.

### BACKGROUND OF THE INVENTION

1. Technical Field

The present invention relates to a method of manufacturing a semiconductor device.

2. Related Art

There is known a technique according to which a wiring pattern of a substrate is opposed to an electrode of a semiconductor chip and then electrically connected to each other. According to this connecting technique, the semiconductor chip is held by a bonding tool with the electrode side of the semiconductor chip facing down, and the wiring pattern of the wiring substrate provided so as to be opposed thereto is subjected to heating and pressurizing, thereby establishing connection.

JP-A-2004-47692 is an example of related art.

### SUMMARY

An advantage of the present invention is to provide a method of manufacturing a semiconductor device according to which an enhanced electrical connection between a semiconductor chip and a substrate having a wiring pattern can be achieved.

1. A method of manufacturing a semiconductor device according to one aspect of the invention includes: (a) preparing a semiconductor chip having a plurality of electrodes; (b) preparing a substrate having a plurality of electrical connection portions; (c) holding the semiconductor chip by a holding tool; (d) planarizing an upper surface of the electrode of the semiconductor chip held by the holding tool; and (e) electrically connecting, after the step (d), the electrode of the semiconductor chip and the electrical connection portion of the substrate.

According to the method of manufacturing a semiconductor device, the step (d) is performed after the step (c). Therefore, it becomes possible to connect the semiconductor chip having the electrode with the connection surface having enhanced fatness to a mounting substrate. As a result, in mounting the semiconductor chip on the substrate, a larger contact area between the electrode and the electrical connection portion can be achieved. For example, in a technique according to which the electrode of the semiconductor chip and the electrical connection portion are electrically connected via conductive particles, the acquisition performance of conductive particles can be enhanced, making it possible to improve electrical connection. Further, it becomes possible to mount on the substrate the semiconductor chip having a plurality of electrodes with enhanced evenness in height, thereby making it possible to suppress variation in mountability among the plurality of electrodes in the single semiconductor chip.

Further, the present invention can also have the following aspects.

2. In the method of the present invention, the step (e) may be performed with the semiconductor chip being kept to be held by the holding tool as in the step (d).

According to this aspect of the present invention, the step (d) and the step (e) are performed with the semiconductor chip being kept to be held by the holding tool. Therefore, it is possible to perform the step (e) with the balance of the holding tool being maintained due to the planarization in the step (d). As a result, in the step (e), it becomes possible to connect the electrical connection portion of the substrate and the electrode of the semiconductor chip while they are parallel to each other even without concerning the balance of the holding tool, thereby making it possible to achieve better electrical connection. As described above, according to the method of manufacturing a semiconductor device in accordance with the invention, it is possible to manufacture a semiconductor device with enhanced reliability.

3. In the method of manufacturing a semiconductor device according to the present invention, the step (d) may include pressing the upper surface of the electrode of the semiconductor chip against a planar surface as an upper surface of a base provided under the semiconductor chip.

4. In the method of manufacturing a semiconductor device according to the present invention, an inclination of the substrate with respect to the semiconductor chip and an inclination of the planar surface with respect to the semiconductor chip may be substantially the same.

According to this aspect, the inclination of the planar surface with respect to the semiconductor chip and the inclination of the substrate with respect to the semiconductor chip are substantially the same. Therefore, it is possible to perform the step (e) with planar state and evenness in height of the electrodes of the semiconductor chip controlled in the step (d) being more reliably maintained. As a result, it is possible to provide a method of manufacturing a semiconductor device in which better electrical connection is achieved.

5. In the method of manufacturing a semiconductor device according to the present invention, the step (d) may include pressing the upper surface of the electrode of the semiconductor chip against a planar surface as the upper surface of the substrate provided under the semiconductor chip.

According to this aspect, the inclination of the planar surface with respect to the semiconductor chip and the inclination of the substrate with respect to the semiconductor chip can be more reliably made to be the same.

6. In the method of manufacturing a semiconductor device, the step (d) may further include applying heat.

According to this aspect, the electrode can be more easily deformed. Therefore, it is possible to reliably perform planarization of the electrode at short times.

### BRIEF DESCRIPTION OF THE DRAWINGS

The invention will be described with reference to the accompanying drawings, wherein like numbers reference like elements.

FIG. 1 is a schematic view for illustrating a step of manufacturing a semiconductor device according to an embodiment.

FIG. 2 is a schematic view for illustrating a step of manufacturing a semiconductor device according to the embodiment.

FIG. 3 is a schematic view illustrating a step of manufacturing a semiconductor device according to the embodiment.

FIG. 4 is a schematic view illustrating a step of manufacturing a semiconductor device according to the embodiment.

FIG. 5 is a schematic view illustrating a step of manufacturing a semiconductor device according to the embodiment.

FIG. 6 is a schematic view illustrating a step of manufacturing a semiconductor device according to the embodiment.

### DESCRIPTION OF EXEMPLARY EMBODIMENTS

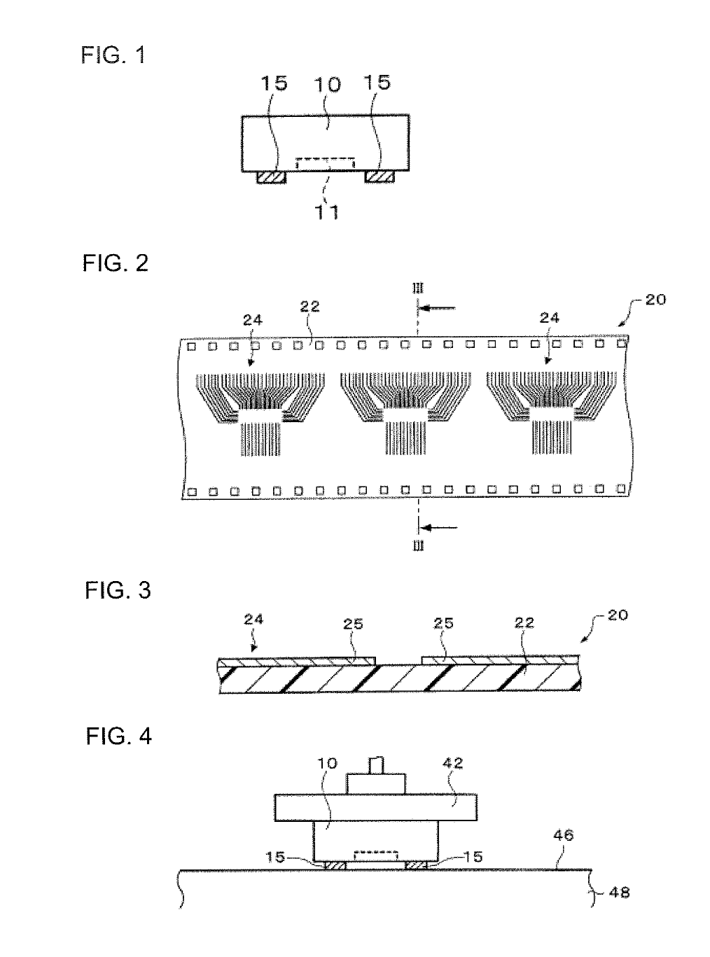

Hereinafter, an embodiment of the invention will be described with reference to the drawings. FIG. 1 to FIG. 6 are views each illustrating a step of manufacturing a semiconductor device according to this embodiment

1. In accordance with the method of manufacturing a semiconductor device of this embodiment, a semiconductor chip 10 as shown in FIG. 1 is first prepared. As shown in FIG. 1, the semiconductor chip 10 is provided with an integrated circuit 11. The integrated circuit 11 is not limited to any specific construction but can include, for example, an active element such as a transistor, or a passive element such as a resistance, a coil, and a condenser. The semiconductor chip 10 has an electrode 15. The electrode 15 can be electrically connected to the inside of the semiconductor chip 10. Further, an electrode, which is not electrically connected to the inside of the semiconductor chip 10, may be also referred to as the electrode 15. The electrode 15 may include, for example, a pad and a bump formed on the pad. In this case, examples of the bump may include a gold bump manufactured by an electrolytic plating technique, a gold bump manufactured by a nonelectrolytic plating technique, and a nickel bump to which gold plating is applied. Further, the semiconductor chip 10 may include, although not shown, a passivation film. The passivation film may be formed by, for example, SiO₂, SiN, or polyimide resin.

2. Next, a substrate 20 is prepared. Hereinafter, the construction of the substrate 20 will be described with reference to the FIG. 2 and FIG. 3. Note that FIG. 2 is a top view of the substrate 20 and FIG. 3 is a partially enlarged cross sectional view taken along the line III-III of FIG. 2.

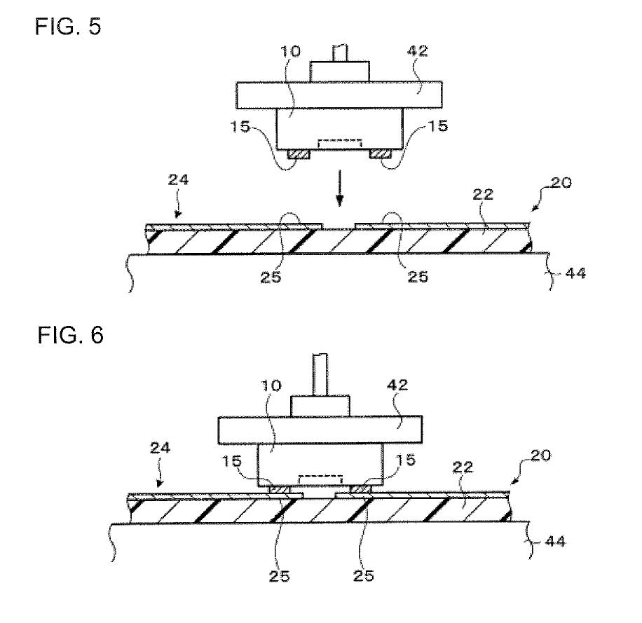

The substrate 20 is composed of a base substrate 22 and a wiring pattern 24 formed on the base substrate 22. The substrate 20 includes a plurality of electrical connection portions 25. As shown in FIG. 5, the electrical connection portion 25 is formed on the surface of the base substrate 22, and may be a portion of the wiring pattern 24. The electrical connection portion 25 is a portion which is utilized for the electrical connection to the electrode 15 of the semiconductor chip 10. In other words, the electrical connection portion 25 is a portion which is to be opposed to and electrically connected to the electrode 15 of the semiconductor chip 10 during the step of mounting the semiconductor chip 10 on the substrate 20 (described later).

First, the base substrate 22 will be described. The material or construction of the base substrate 22 is not particularly limited, and any one of well known substrates may be utilized as the base substrate 22. The base substrate 22 may be a flexible substrate, a rigid substrate, or a tape substrate. Further, the base substrate 22 may be a multilayer type substrate or a single layer substrate. Further, also the outer shape of the base substrate 22 should not be construed restrictively. Furthermore, also the material of the base substrate 22 should not be construed restrictively. The base substrate 22 may be formed of any one of organic materials and inorganic materials, or a composite structure thereof. Examples of the base substrate 22 formed of an organic material may include substrate (including a film) composed of polyethylene terephthalate (PET) and a flexible substrate composed of polyimide resin. As the flexible substrate, there may be used a tape used for a Flexible Printed Circuit (FPC) or in a Tape Automated Bonding (TAB) technique. Further, as the base substrate 22 formed of an inorganic material, there may be used, for example, a ceramics substrate or a glass substrate. An example of the composite structure of organic and inorganic materials may be a glass epoxy substrate.

Next, the wiring pattern 24 formed on the substrate 20 will be described. Referring to FIG. 5, the wiring pattern 24 may be formed on the surface of the base substrate 22. When the base substrate 22 has a tape-like shape, a plurality of wiring patterns 24 may be formed on the single base substrate 22. In this case, the region of the single base substrate 22 on which each wiring pattern 24 is formed may be refereed to as the substrate 20. The structure of the wiring pattern 24 should not be construed restrictively, but it may be formed of a single metal layer or a plurality of metal layers. The wiring pattern 24 may have a structure in which any one of copper (Cu), chrome (Cr), titan (Ti), nickel (Ni), titan tungsten (Ti—W) and the like is laminated. Note that the wiring pattern 24 may include en inner wiring (not shown) extending though the inside of the base substrate 22.

Further, the substrate 20 can include a resin layer (not shown; also referred to as “solder resist layer”). In this case, the resin layer may be formed so as to partially cover the wiring pattern 24. When the base substrate 22 is composed of a glass, the wiring pattern 24 may be formed by an Indium Tin Oxide (ITO) Electrode or other metals.

3. Next, as shown in FIG. 4, by using a holding tool (hereinafter referred to as “bonding tool”) 42, the semiconductor chip 10 is held such that the surface on which the electrode 15 of the semiconductor chip 10 is formed faces down. Note that the bonding tool 42 has a suction mechanism, thereby holding the semiconductor chip 10 by suction. Further, in the semiconductor chip 10, the upper surface of the electrode 15 (the surface to be connected to the substrate 20 during the step described later) is pressed against a planar surface 46 which is separately prepared, thereby planarizing the upper surface of the electrode 15. As a base 48 having the planar surface 46 is not limited to a specific one so far as it has a planar surface and enough strength to prevent the planar surface 46 from deforming even if the semiconductor chip 10 is pressed thereagainst. For example, the glass substrate may be used as the base 48.

Further, the base 48 may be arranged on the supporting board (not shown). In this case, it is preferable that the supporting board include a heating mechanism or the like. This is because, during this planarizing process, the electrode 15 is pressed against the planar surface 46 and then heat is applied thereto, thereby making it possible to easily deform the electrode 15 and to more easily planarize the electrode 15. Note that the heating mechanism may be provided on the bonding tool 42 side.

Further, at least one of the planar surface 46 and the upper surface of the electrical connection portion 25 of the substrate 20 is preferably parallel to the conductor chip 10. This is because it becomes then possible to suppress the unevenness in height among a plurality of electrodes 15, to provide an enhanced electrical connection over the entire semiconductor chip, thereby enhancing reliability.

Further, it is preferable that the inclination of the planar surface 46 with respect to the semiconductor chip 10 and the inclination of the substrate 20 with respect to the semiconductor chip 10 be substantially the same. In this case, specifically, the inclination means the extent to which, provided that a surface parallel to the upper surface of the electrode 15 of the semiconductor chip 10 is a reference surface, the planar surface 46 or the upper surface of the electrical connection portion 25 of the substrate 20 is deviated from the reference surface. For example, when the inclinations of the planar surface 46 or of the upper surface of the electrical connection portion 25 of the substrate 20 are different, even if the plurality of the electrodes 15 have the same height with respect to the planar surface 46, they does have different height with respect to the upper surface of the electrical connection portion 25 of the substrate 20. This leads to, for example, variation in resistance value among the plurality of the electrodes 15 after being mounted on the substrate 20, which may contribute to degradation of reliability. In order to suppress the above problems, it is therefore preferable that the inclinations of the planar surface 46 and of the substrate 20 be substantially the same.

4. Next, as shown in FIG. 5 and FIG. 6, the semiconductor chip 10 having the electrode 15 thus planarized is then mounted on the substrate 20. In this process, as shown in FIG. 5, the semiconductor chip 10 having the electrode with a planarized surface is first caused to face the wiring pattern of the substrate 20 while being held by and not being come off from the bonding tool 42. Then, as shown in FIG. 6, it becomes possible to press the semiconductor chip 10 and the substrate 20 against each other to thereby connecting them with each other by using the supporting board 44 and the bonding tool 42. In this case, a eutectic alloy may be formed by the electrode 15 and the electrical connection portion 25. In other words, the electrode 15 and the electrical connection portion 25 may be bonded through a eutectic alloy. Alternatively, the electrode 15 and the electrical connection portion 25 may be electrically connected to each other through the intermediation of conductive particles (not shown) in a non-contact manner.

The method of manufacturing a semiconductor device according to this embodiment may include forming a sealing resin (not shown). Then, it is possible to manufacture a semiconductor device according to this embodiment after an inspection process, punching process and the like.

According to the method of manufacturing a semiconductor device of the invention, the step (4) is performed after the step (3). Therefore, it becomes possible to connect to the mount substrate 20 the semiconductor chip 10 having the electrode 15 with connection surface having enhanced flatness. As a result, it is possible to enlarge the overlapping area of the electrode 15 and the electrical connection portion 25 in mounting the semiconductor chip 10 on the substrate 20. For example, in the case of a technique in which the electrode 15 of the semiconductor chip 10 and the electrical connection portion 25 are electrically connected to each other via conductive particles, it is possible to enhance acquisition performance of conductive particles, thereby improving electrical connection. Further, it becomes possible to mount on the substrate the semiconductor chip having a plurality of electrodes 15 with enhanced evenness in height. As a result, it is possible to suppress variation in mountability among the plurality of electrodes in the single semiconductor chip. It should be noted that the above-mentioned “overlapping area” means an overlapping area which exists between the upper surface of the electrode 15 and the upper surface of the electrically connecting portion 25 while maintaining substantially the same distance therebetween.

Further, the step (3) and the step (4) are performed while the semiconductor chip is held by the holding tool. Therefore, the step (4) can be performed with the balance of the bonding tool 42 being maintained due to the planarization in the step (3). As a result, in the step (4), it becomes possible to connect the electrical connection portion 25 of the substrate 20 and the electrode 15 of the semiconductor chip 10 while being parallel to each other even without concerning the balance of the bonding tool 42. Thus, it becomes possible to achieve better electrical connection. As described above, according to the method of manufacturing a semiconductor device of the invention, it is possible to manufacture a semiconductor device having enhanced reliability. Moreover, the step (c) and the step (d) are not necessarily sequentially performed. They may be also performed independently from each other. For instance, it is also possible to perform the step (c) for a wafer before dicing. In this case, a number of products (a plurality of semiconductor devices) can be collectively subjected to planarization.

When the semiconductor chip 10 is a driving IC for a liquid crystal panel, it is possible to use, as the substrate 20, a glass substrate on which the wiring pattern is formed. In this case, a predetermined surface of the glass substrate can be the planar surface 46. In this case, the condition for the substrate 20 and that for the planar surface 46 can be the same. Therefore, when a semiconductor device is manufactured according to the above-mentioned method, it becomes possible to achieve good electrical connection, thereby making it possible to manufacture a semiconductor device with enhanced reliability.

It should be noted that the present invention is not limited to the above-mentioned embodiment and many variations are possible. For example, the present invention may include a construction which is substantially the same as the construction described above (for example, a construction which is similar in function, method and result or in purpose and effect to the above-mentioned construction). Further, the present invention may include a construction in which a part that is not essential of the construction described above is substituted. Moreover, the present invention may include a construction with which the same operation and effects as of the construction described above can be achieved, or a construction with which the same purpose as of the construction described above can be achieved. Furthermore, the present invention may include a construction which is achieved by adding a known technique to the construction described above.

What is claimed is:

1. A method of manufacturing a semiconductor device, comprising:
(a) preparing a semiconductor chip having a plurality of electrodes;
(b) preparing a substrate having a plurality of electrical connection portions;
(c) holding the semiconductor chip by a holding tool;
(d) planarizing an upper surface of the electrode of the semiconductor chip held by the holding tool; and
(e) electrically connecting, after the step (d), the electrode of the semiconductor chip and the electrical connection portion of the substrate.

2. The method of manufacturing a semiconductor device according to claim 1, wherein the step (e) is performed with the semiconductor chip being kept to be held by the holding tool as in the step (d).

3. The method of manufacturing a semiconductor device according to claim 1, wherein the step (d) includes pressing the upper surface of the electrode of the semiconductor chip against a planar surface as an upper surface of a base provided under the semiconductor chip.

4. The method of manufacturing a semiconductor device according to claim 3, wherein an inclination of the substrate with respect to the semiconductor chip and an inclination of the planar surface with respect to the semiconductor chip are substantially the same.

5. The method of manufacturing a semiconductor device according to claim 1, wherein the step (d) includes pressing the upper surface of the electrode of the semiconductor chip against a planar surface as the upper surface of the substrate provided under the semiconductor chip.

6. The method of manufacturing a semiconductor device according to claim 3, wherein the step (d) further comprising applying heat.
